(19) United States
(12) Patent Application Publication
(10) Pub. No.: US 2003/0221147 A1
(43) Pub. Date: Nov. 27, 2003

(54) Compression test circuit

(75) Inventor: Shu-Liang Nin, Taoyuan City (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/329,961

(22) Filed: Dec. 26, 2002

(30) Foreign Application Priority Data
May 21, 2002 (TW) 91110683

(51) Int. Cl. G11C 29/00

(52) U.S. Cl. 714/718

(57) ABSTRACT

A compression test circuit. The circuit tests a memory array, wherein the memory array has a plurality of memory cells pre-programmed with a test bit, each outputting an output bit. The compression test circuit comprises a compression unit, a transfer circuit and an output comparison unit. The compression test circuit outputs an output signal of logic one or logic zero according to the test bit written into the predetermined number of the memory cells, and outputs an error signal when at least one defective memory cell is detected.

### BACKGROUND OF THE INVENTION

1. Field of the Invention

The present invention relates in general to an output control circuit. In particular, the present invention relates to a compression test circuit for determining whether the memory cells of a memory array are effective. The compression test circuit further can obtain the expected value (test bit) of the memory cells, such that the failure type of the defective memory cells also can be determined.

2. Description of the Related Art

Semiconductor memories such as dynamic random access memories have literally millions of memory storage cells. These storage cells are typically fabricated with individual capacitors as the memory elements and include access transistors. The cells are arranged in rows and columns. A memory cell array refers to these cells as organized in rows and columns. To ensure that a particular memory device is fully operational, each of the individual memory cells within the device is operationally tested.

As semiconductor memory technology has evolved, the typical memory device increasingly stores more and more individual memory cells. This increase in the population of memory cells in a memory device correspondingly increases the possibility of defects within one or more memory cells and has also increased the time required to test all the cells. Therefore, the need for rapidly testing the cells of a memory device has become even more crucial.

However, because the typical memory device has so many individual memory cells, testing each individual cell can be time consuming. A typical testing method writes a test bit to a memory cell, reads an output bit from the memory cell, and compares the output bit to the test bit. This last step is the error-checking step. If an error is found, i.e., the output bit is not identical to the test bit, a redundant memory cell is used to replace the defective cell.

Because this testing method is so time consuming, various solutions have been proposed to decrease testing time. One is to write a test bit to a predetermined number of memory cells concurrently, reading the output bits of the memory cells, compressing the output bits into a compressed bit, and error checking only the compressed bit. If at least one of the predetermined number of memory cells is defective, the compressed bit will be in error.

This solution is typically called data compression test mode. It is less time consuming in that a number of memory cells are tested at one time, as opposed to each memory cell being tested at a time.

As shown in FIG. 1, in the compression test method, the output bits read from a predetermined number of memory cells DQ0˜DQn are compressed by a XOR gate 10. The XOR gate outputs a compressed bit of logic zero when all output bits are identical to the test bit. The compressed bit of logic zero means that the predetermined number of memory cells are effective. Further, the XOR gate outputs a compressed bit of logic one when at least one test bit isn't identical to the test bit. The compressed bit of logic one means that at least one of the predetermined number of memory cells is defective.

However, the compressed bit of logic zero means the predetermined number of memory cells are effective only, but the test bit stored in the predetermined number of memory cells is logic zero. Also, the compressed bit of logic one means the predetermined number of memory cells are effective only, but test bit stored in the predetermined number of memory cells is logic zero. Consequently, the conventional method described only determines whether the memory cells are effective, but not the failure types of the defective memory cells. Namely, the conventional method above cannot determine if the failure type of the defective memory cells is one-fault or zero-fault. If one-fault, a test bit of logic one is written to a memory cell, but the output bit of the memory cell is not identical to logic one. Further, zero-fault means that a test of logic zero is written to a memory cell, but the output bit of the memory cell is not identical to logic zero.

### SUMMARY OF THE INVENTION

It is an object of the present invention to provide a compression test circuit to test whether memory cells of a memory array are defective, and to further determine the failure type of the defective memory cells.

In the present invention, the compression test circuit compresses output bits read from a determined number of memory cells of a memory array to a compressed bit. The compression test circuit then outputs an error signal when at least one of the predetermined number of memory cells is defective. When all the predetermined number of memory cells are effective, the compression test circuit outputs an output bit of logic one to indicate that the test bit stored in the memory is logic one or outputs an output bit of logic zero to indicate that the test bit stored in the memory is logic zero.

Therefore, the present invention can quickly determine whether memory cells of a memory array are defective, and to further obtain the failure type of the defective memory cells. Consequently, process operators can improve process quality knowing the failure type of the defective memory cells, and further improve throughput.

In the present invention, the compression test circuit is used to test a memory array, wherein the memory array has a plurality of memory cells pre-programmed with a test bit, each outputting an output bit. The compression test circuit comprises a compression unit, a transfer circuit, and an output comparison unit. The compression unit receives the output bits from a predetermined number of memory cells of the memory array each time, outputs a first signal when all output bits from the determined number of memory cells are identical, and outputs a second signal when at least one of the output bits from the determined number of memory cells is different to the others. The transfer circuit has an input terminal coupled to one of the output bits from the determined number of memory cells, and outputs the coupled output bit according to the first signal and the second signal. The output comparison circuit outputs the output bit form the transfer circuit when receiving the first signal and outputs an error signal when receiving the second signal.

### DESCRIPTION OF THE DRAWINGS

For a better understanding of the present invention, reference is made to a detailed description to be read in conjunction with the accompanying drawings, in which:

FIG. 1 is a diagram of a conventional compression-testing mode.

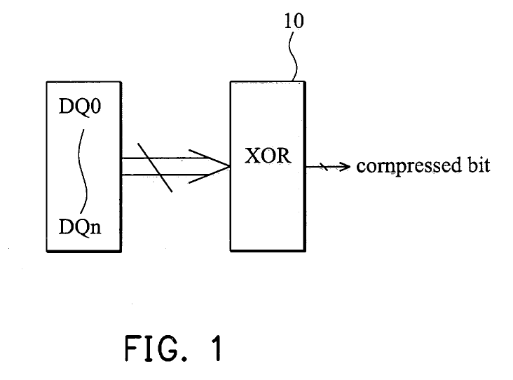

FIG. 2 is an operating diagram of the compression test circuit of the present invention.

FIG. 3 shows circuit structure of the compression test circuit of the present invention.

FIG. 4 shows another circuit structure of the compression test circuit of the present invention.

### DETAILED DESCRIPTION OF THE INVENTION

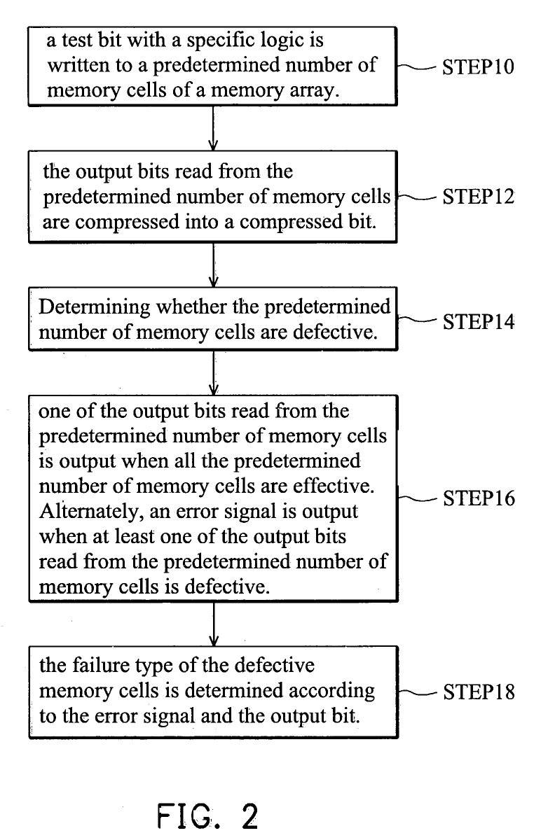

FIG. 2 shows the operating flow of the present invention. First, in step 10, a test bit with a specific logic is written to a predetermined number of memory cells of a memory array. Namely, a test bit of logic one is written to all of the predetermined number of memory cells, or a test bit of logic zero is written to all of the predetermined number of memory cells. Next, each test bit stored in each the predetermined number of memory cells is read out as an output bit.

In step 12, the output bits read from the predetermined number of memory cells are compressed into a compressed bit. Next, in step 14, error checking determines whether the predetermined number of memory cells are defective.

In step 16, one of the output bits read from the predetermined number of memory cells is output when all the predetermined number of memory cells are effective. Alternately, an error signal is output when at least one of the output bits read from the predetermined number of memory cells is defective. Thereafter, in step 18, the failure type of the defective memory cells is determined according to the error signal and the output bit, namely, the test bit written to the each memory cell.

For example, a test bit of logic one is written to a predetermined number of memory cells, and each output bit read from the predetermined number of memory cells is logic one if all of the predetermined number of memory cells are effective. However, if the output bit read from the memory cell is logic zero, the memory cell is defective. In step 12, the output bits of the predetermined number of memory cells are compressed to a compressed bit of logic zero if all the predetermined number of memory cells are effective. Alternately, the output bits of the predetermined number of memory cells are compressed to a compressed bit of logic one if at least one of the predetermined number of memory cells is defective.

On the contrary, a test bit of logic zero is written to a predetermined number of memory cells, each output bit read from the predetermined number of memory cells is logic zero if all of the predetermined number of memory cells are effective. However, the output bit read from the memory cell is logic one if the memory cell is defective. In step 12, the output bits of the predetermined number of memory cells are compressed to a compressed bit of logic zero if all the predetermined number of memory cells are effective. Alternately, the output bits of the predetermined number of memory cells are compressed to a compressed bit of logic one if at least one of the predetermined number of memory cell is defective.

Therefore, if the compressed bit is logic one, at least one of the predetermined number of memory cells is defective. If the compressed bit is logic zero, all of the predetermined number of memory cells are effective. In step 16, an error signal is then output when at least one of the predetermined number of memory cells is defective. Alternately, one of the test bits stored in the memory cells is output when all the predetermined number of memory cells are effective.

Consequently, in step 18, the failure type of the defective memory cells is one-fault when the error signal is output and the test bit is logic one. Alternately, the failure type of the defective memory cells is zero-fault when the error signal is output and the test bit is logic zero.

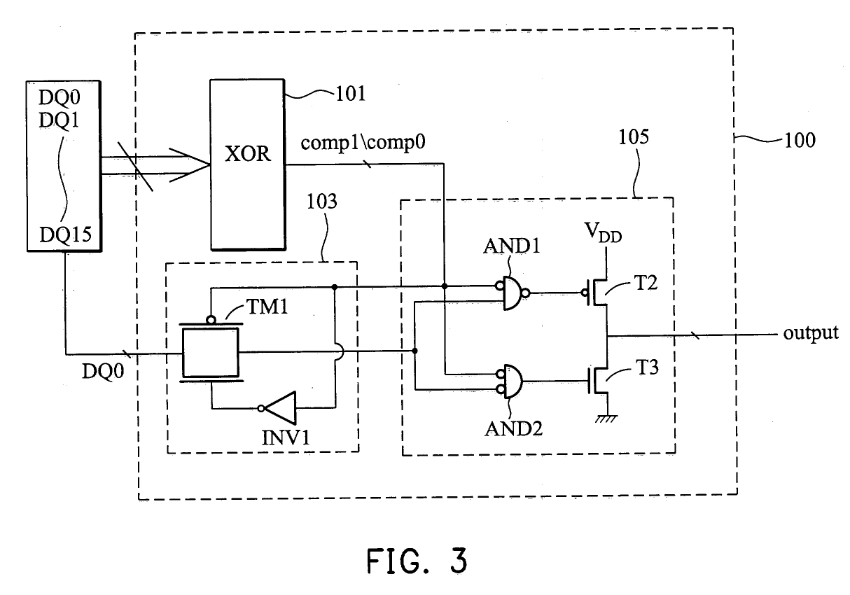

FIG. 3 shows a compression test circuit of the present invention, the compression test circuit comprises a compression unit 101, a transfer circuit 103 and an output comparison unit 105.

The compression unit 101 is composed of a XOR gate having an output terminal and a plurality of input terminals, for example sixteen input terminals, for receiving output bits DQ0˜DQ15. The compression unit 101 outputs a first signal comp0 as a compressed bit when all output bits DQ0˜DQ15 are identical. Alternately, the compression unit 101 outputs a second signal comp1 as the compressed bit when at least one of the output bits DQ0˜DQ15 is different.

The transfer circuit 103 is composed of a transfer gate TM1 and a inverting gate INV1. The transfer gate TM1 has an input terminal coupled to one of the output bits DQ0˜DQ15, for example DQ0, a first control terminal coupled to the output terminal of the compressed unit 101, a second control terminal and an output terminal. Further, the inverting gate INV1 has an input terminal and an output terminal coupled to the first control terminal and the second control terminal respectively.

The output comparison unit 105 is composed of a first AND gate AND1, a second AND gate AND2, a p-type transistor T2 and a N-type transistor T3. The first AND gate AND1 has a first inverting input terminal and a first non-inverting input terminal coupled to the output terminals of the compression unit 101 and the transfer circuit 103 respectively, and a first inverting output terminal. The second AND gate AND2 has a second inverting input terminal and a third inverting input terminal coupled to the output terminals of the compression unit 101 and the transfer circuit 103 respectively, and a second non-inverting output terminal. The P-type transistor T2 has a source terminal coupled to a source voltage VDD, a gate terminal coupled to an inverting output terminal of the first AND gate, and a drain terminal. The N-type transistor T3 has a drain terminal coupled to ground, a gate terminal coupled to a non-inverting output terminal of the second AND gate, and a source terminal coupled to the drain terminal of the P-type transistor T2 as to an output terminal of the output compression circuit 100.

The operation of the compression test circuit 100 according to the present invention is illustrated in FIG. 3.

First, after writing a test bit of logic one into a predetermined number of memory cells of a memory array by an external circuit (not shown in FIG. 3), the output bits DQ0˜DQ15 of the predetermined number of memory cells are output to the input terminals of the compression unit 101. The compression unit 101 outputs the first signal comp0 when output bits DQ0˜DQ15 are logic one and outputs the second signal comp1 when at least one of the output bits DQ0˜DQ15 is not logic one.

When all the output bits DQ0˜DQ15 are logic one, the first signal comp0 of logic zero is output to the first control terminal of the transfer gate TM1, the input terminal of the inverting gate INV1, the inverting input terminal of the first AND gate AND1 and the inverting input terminal of the second AND gate AND2. The transfer circuit 103 then outputs the output bit DQ0 to the non-inverting input terminal of the first AND gate AND1 and the inverting input terminal of the second AND gate AND2 according to the first signal comp0. Next, the P-type transistor T2 is turned on and the N-type transistor T3 is turned off because the first signal comp0 is logic zero and the DQ0 is logic one. Therefore, the compression test circuit 100 outputs an output signal of logic one the same as the test bit.

Alternately, when at least one of the output bits DQ0˜DQ15 is not logic one, the second signal comp1 of logic one is output to the first control terminal of the transfer gate TM1, the input terminal of the inverting gate INV1, the inverting input terminal of the first AND gate AND1 and the inverting input terminal of the second AND gate AND2. Then the transfer circuit 103 outputs the output bit DQ0 to the non-inverting input terminal of the first AND gate AND1 and the inverting input terminal of the second AND gate AND2 according to the second signal comp1. Next, the P-type transistor T2 is turned off and the N-type transistor T3 is turned off because the second signal comp1 is logic one and the DQ0 is logic one. Therefore, the compression test circuit 100 outputs an error signal of hi-Z (high impedance).

On the contrary, after writing a test bit of logic zero into a predetermined number of memory cells of a memory array by an external circuit (not shown in FIG. 3), the output bits DQ0˜DQ15 of the predetermined number of memory cells are output to the input terminals of the compression unit 101. The compression unit 101 outputs the first signal comp0 when all the output bits DQ0˜DQ15 are logic zero and outputs the second signal comp1 when at least one of the output bit DQ0˜DQ15 is not logic zero.

When all the output bits DQ0˜DQ15 are logic zero, the first signal comp0 of logic zero is output to the first control terminal of the transfer gate TM1, the input terminal of the inverting gate INV1, the inverting input terminal of the first AND gate AND1 and the inverting input terminal of the second AND gate AND2. Then the transfer circuit 103 outputs the output bit DQ0 to the non-inverting input terminal of the first AND gate AND1 and the inverting input terminal of the second AND gate AND2 according to the first signal comp0. Next, the P-type transistor T2 is turned off and the N-type transistor T3 is turned on because the first signal comp0 is logic zero and the DQ0 is logic zero. Therefore, the compression test circuit 100 outputs an output signal of logic zero the same as the test bit.

Alternately, when at least one of the output bits DQ0˜DQ15 is not logic zero, the second signal comp1 of logic one is output to the first control terminal of the transfer gate TM1, the input terminal of the inverting gate INV1, the inverting input terminal of the first AND gate AND1 and the inverting input terminal of the second AND gate AND2. Then the transfer circuit 103 outputs the output bit DQ0 to the non-inverting input terminal of the first AND gate AND1 and the inverting input terminal of the second AND gate AND2 according to the second signal comp1. Next, the P-type transistor T2 is turned off and the N-type transistor T3 is turned on because the second signal comp1 is logic one and the DQ0 is logic zero. Therefore, the compression test circuit 100 outputs an error signal of hi-Z.

The test bit written into the predetermined number of the memory cells is logic one when the compression test circuit 100 outputs an output signal of logic one. Alternately, the test bit written into the predetermined number of the memory cells is logic zero when the compression test circuit 100 outputs an output signal of logic zero.

Furthermore, at least one defective memory cells is detected when the compression test circuit outputs an error signal of hi-z. Then, the failure type of the defective memory is determined according to the test bit and the error signal. For example, the failure type of defective memory cells is one-fault if the test bit written into the predetermined number of the memory cells is logic one but the compression test circuit outputs an error signal. Alternately, the failure type of defective memory cells is zero-fault if the test bit written into the predetermined number of the memory cells is logic zero but the compression test circuit outputs an error signal.

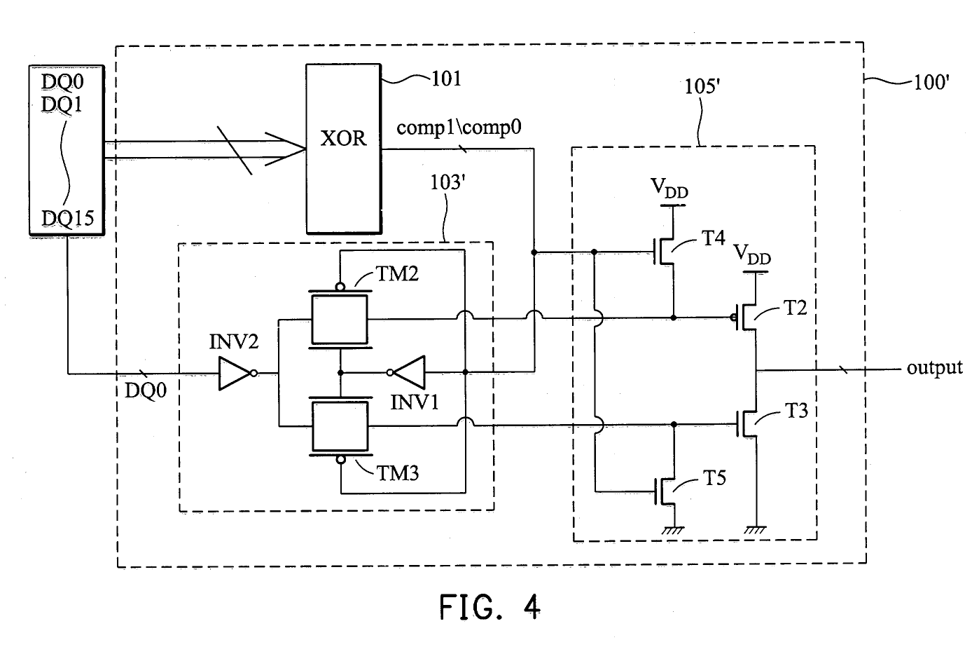

Also, another embodiment according to the present invention is proposed as follows. For brevity, the elements in FIG. 4 the same as or similar with the elements in FIG. 3 are depicted by the same numerals or notations.

In FIG. 4, transfer circuit 103 is composed of two inverters INV2 and INV3, and two transfer gates TM2 and TM3. The input terminal of the inverter INV2 is coupled to one of the output bits DQ0˜DQ15, for example DQ0. The output terminal of the inverter INV2 is coupled to the input terminals of the transfer gate TM2 and TM3. The first control terminals of the transfer gate TM2 and TM3 and the input terminal of the inverter INV2 are couple to the output terminal of the compression unit 101, and the second control terminals of the transfer gate TM2 and TM3 are coupled to the output terminal of the inverter INV2.

The output comparison unit 105′ is composed of transistors T2 to T5. The gate terminals of the transistor T4 and T5 are coupled to the output terminal of the compression unit 101, and the source terminal of the transistor T4 and the drain terminal of the transistor T5 are coupled to the output terminals of the transfer gate TM2 and TM3 respectively. Further, the drain terminal of the transistor T4 is coupled to the voltage source VDD, and the source terminal of the transistor T5 is coupled to ground. The source terminals of the transistor T2 and T3 are coupled to the voltage source VDD and ground respectively, and the gate terminal of the transistor T2 is coupled to the source terminal of the transistor T4 and the output terminal of the transfer gate TM2. The gate terminal of the transistor T5 is coupled to the drain terminal of the transistor T5 and the output terminal of the transfer gate TM3. The drain terminal of the transistor T2 and the source terminal of the transistor T3 are coupled to together to serve as the output terminal of the output comparison unit 105′.

The operation of the compression test circuit shown in FIG. 4 is illustrated as follows. First, after writing a test bit of logic one into a predetermined number of memory cells of a memory array by an external circuit (not shown in FIG. 4), the output bits DQ0˜DQ15 of the predetermined number of memory cells are output to the input terminals of the compression unit 101. The compression unit 101 outputs the first signal comp0 when output bits DQ0˜DQ15 are logic one and outputs the second signal comp1 when at least one of the output bits DQ0˜DQ15 is not logic one.

When all the output bits DQ0˜DQ15 are logic one, the first signal comp0 of logic zero is output to the gate terminals of the transistors T4 and T5 and the input terminal of the inverter INV3. The transfer circuit 103 then outputs the inverse signal of the output bit DQ0 to the gate terminal of the transistor T4, the source terminal of the transistor T5 and the gate terminals of the transistors T2 and T3 through the inverter INV2 according to the first signal comp0. Next, the transistors T3, T4 and T5 are turned off and the transistor T2 is turned on because the first signal comp0 is logic zero and the DQ0 is logic one. Therefore, the compression test circuit 100 outputs an output signal of logic one the same as the test bit.

Alternately, when at least one of the output bits DQ0˜DQ15 is not logic one, the first signal comp0 of logic zero is output to the gate terminals of the transistors T4 and T5 and the input terminal of the inverter INV3. Then the transfer circuit 103 outputs the inverse signal of the output bit DQ0 to the gate terminal of the transistor T4, the source terminal of the transistor T5 and the gate terminals of the transistors T2 and T3 through the inverter INV2 according to the second signal comp1. Next, the transistors T2 and T3 are turned off and the transistors T4 and T5 are turned on because the second signal comp1 is logic one. Therefore, the compression test circuit 100 outputs an error signal of hi-Z (high impedance).

On the contrary, after writing a test bit of logic zero into a predetermined number of memory cells of a memory array by an external circuit (not shown in FIG. 4), the output bits DQ0˜DQ15 of the predetermined number of memory cells are output to the input terminals of the compression unit 101. The compression unit 101 outputs the first signal comp0 when all the output bits DQ0˜DQ15 are logic zero and outputs the second signal comp1 when at least one of the output bit DQ0˜DQ15 is not logic zero.

When all the output bits DQ0˜DQ15 are logic zero, the first signal comp0 of logic zero is output to the gate terminals of the transistors T4 and T5 and the input terminal of the inverter INV3. Then the transfer circuit 103 outputs the inverse signal of the output bit DQ0 to the gate terminal of the transistor T4, the source terminal of the transistor T5 and the gate terminals of the transistors T2 and T3 through the inverter INV2 according to the first signal comp0. Next, the transistors T2, T4 and T5 are turned off and the transistor T3 is turned on because the first signal comp0 is logic zero and the DQ0 is logic zero. Therefore, the compression test circuit outputs an output signal of logic zero the same as the test bit.

Alternately, when at least one of the output bits DQ0˜DQ15 is not logic zero, the second signal comp1 of logic one is output to the gate terminals of the transistors T4 and T5 and the input terminal of the inverter INV3. Then the transfer circuit 103 outputs the inverse signal of the output bit DQ0 to the gate terminal of the transistor T4, the source terminal of the transistor T5 and the gate terminals of the transistors T2 and T3 through the inverter INV2 according to the second signal comp1. Next, the transistors T2 and T3 are turned off and the transistors T4 and T5 are turned on because the second signal comp1 is logic one. Therefore, the compression test circuit outputs an error signal of hi-Z.

The test bit written into the predetermined number of the memory cells is logic one when the compression test circuit 100 outputs an output signal of logic one. Alternately, the test bit written into the predetermined number of the memory cells is logic zero when the compression test circuit 100 outputs an output signal of logic zero.

Furthermore, at least one defective memory cells is detected when the compression test circuit outputs an error signal of hi-z. Then, the failure type of the defective memory is determined according to the test bit and the error signal. For example, the failure type of defective memory cells is one-fault if the test bit written into the predetermined number of the memory cells is logic one but the compression test circuit outputs an error signal. Alternately, the failure type of defective memory cells is zero-fault if the test bit written into the predetermined number of the memory cells is logic zero but the compression test circuit outputs an error signal.

Therefore, the present invention can quickly determine whether memory cells of a memory array are defective, and further obtain the failure type of the defective memory cells. Consequently, process operators can improve the process quality according to the failure type of the defective memory cells, and further improve throughput of the process.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A compression test circuit for testing a memory array, wherein the memory array has a plurality of memory cells pre-programmed with a test bit, each of the memory cells outputting an output bit, the circuit comprising:
a compression unit for receiving the output bits from a determined number of memory cells of the memory array each time, the compression outputs a first signal when all output bits from the determined number of memory cells are identical, and outputs a second signal when at least one of the output bits from the determined number of memory cells is different;
a transfer circuit having an input terminal coupled to one of the output bits from the determined number of memory cells, the transfer circuit outputting the coupled output bit according to the first signal and the second signal;
an output comparison unit having a first terminal and a second terminal coupled to the compression unit and the transfer circuit respectively, the output comparison circuit outputting the output bit from the transfer circuit when receiving the first signal and outputting an error signal when receiving the second signal.

2. The compression test circuit as claimed in claim 1, wherein the compression unit is a XOR gate.

3. The compression test circuit as claimed in claim 1, wherein transfer circuit is composed of a transfer gate and an inverter.

4. The compression test circuit as claimed in claim 1, wherein the output comparison circuit composes:
a first AND gate having a first inverting input terminal and a first non-inverting input terminal coupled to the outputs of the compression unit and the transfer circuit;
a second AND gate having a second inverting input terminal and a third inverting input terminal coupled to outputs of the compression unit and the transfer circuit;
a P-type transistor having a source terminal coupled to a source voltage, a gate terminal coupled to an inverting output terminal of the first AND gate, and a drain terminal;
a N-type transistor having a drain terminal coupled to ground, a gate terminal coupled to a non-inverting output terminal of the second AND gate, and a source terminal coupled to the drain terminal of the P-type transistor as to an output terminal of the output compression circuit.

5. The compression test circuit as claimed in claim 1, wherein the compression unit is a XOR gate with sixteen input terminals and one output terminal.

6. The compression test circuit as claimed in claim 1, wherein the transfer circuit composes:
a first inverter having input terminals the output bits from the determined number of memory cells, and an output terminal;
a first transfer gate having an input terminal coupled to the output terminal of the first inverter, and a first control terminal and a second control terminal;
a second transfer gate having an input terminal coupled to the output terminal of the first inverter, and a first control terminal and a second control terminal;
a second inverter having an input terminal coupled to the first control terminals of the first transfer gate and the second transfer gate, and an output terminal coupled to the second control terminals of the first transfer gate and the second transfer gate.

7. The compression test circuit as claimed in claim 6, wherein the output comparison unit comprises:
a first transistor having a gate terminal coupled to the output terminal of the first transfer gate, a drain terminal coupled to a voltage source, and a source terminal;
a second transistor having a gate terminal coupled to the gate of the first transistor, a drain terminal coupled to the output terminal of the second transfer gate, and a source terminal coupled to ground;
a third transistor having a source terminal coupled to the voltage source, a gate terminal coupled to the source terminal of the first transistor and the output terminal of the first transfer gate, and a source terminal as the output terminal of the output comparison circuit; and
a fourth transistor having a source terminal coupled to ground, a gate terminal coupled to drain terminal of the second transistor and the output terminal of the second transfer gate, and a drain terminal coupled to the drain terminal of the third transistor.
